(19) United States
(12) Patent Application Publication
(10) Pub. No.: US 2025/0386522 A1
(43) Pub. Date: Dec. 18, 2025

(54) SEMICONDUCTOR DEVICE INCLUDING SUPPORTING FRAME AND MANUFACTURING METHOD OF THE SAME

(71) Applicant: NANYA TECHNOLOGY CORPORATION, NEW TAIPEI CITY (TW)

(72) Inventor: CHUN-HENG WU, NEW TAIPEI CITY (TW)

(21) Appl. No.: 18/765,562

(22) Filed: Jul. 8, 2024

Related U.S. Application Data
(62) Division of application No. 18/743,380, filed on Jun. 14, 2024.

(51) Int. Cl. H10B 12/00

(52) U.S. Cl. CPC H10D 1/042; H10B 12/31; H10D 1/714; H10D 1/716

(57) ABSTRACT

A semiconductor device and method for manufacturing the same are provided. The semiconductor device includes a substrate, a lower supporting frame; an upper supporting frame, and a capacitor component. The lower supporting frame is disposed over the substrate. The upper supporting frame is disposed over and spaced apart from the lower supporting frame. The capacitor component is disposed over the substrate. The capacitor component includes a lower electrode having a noncontinuous sidewall abutting the lower supporting frame.

### CROSS-REFERENCE TO RELATED APPLICATION

This application is a divisional application of U.S. Non-Provisional Application No. 18/743,380 filed June 14, 2024, which is incorporated herein by reference in its entirety.

### TECHNICAL FIELD

The present disclosure relates to a semiconductor device and method for manufacturing the same, and more particularly, to a semiconductor device including supporting frames and method for manufacturing the same.

### DISCUSSION OF THE BACKGROUND

With integrated circuits (ICs) achieving regular increases in performance and miniaturization, advances in materials and design produce successive generations with smaller and more complex circuits.

As the semiconductor industry develops, reducing overlay errors in lithography operations is becoming much more important. For example, when defining a pattern of a conductive wire to connect a landing pad, a relatively great overlay error may result in the conductive wire being misaligned with the landing pad, which may cause the material of the conductive wire to fill the air gap of an isolation spacer and negatively affect the electrical parameter of the a semiconductor device. Therefore, a new semiconductor device and method of improving such problems is required.

This Discussion of the Background section is provided for background information only. The statements in this Discussion of the Background are not an admission that the subject matter disclosed herein constitutes prior art with respect to the present disclosure, and no part of this Discussion of the Background may be used as an admission that any part of this application constitutes prior art with respect to the present disclosure.

### SUMMARY

One aspect of the present disclosure provides a semiconductor device. The semiconductor device includes a substrate, a lower supporting frame; an upper supporting frame, and a capacitor component. The lower supporting frame is disposed over the substrate. The upper supporting frame is disposed over and spaced apart from the lower supporting frame. The capacitor component is disposed over the substrate. The capacitor component includes a lower electrode having a noncontinuous sidewall abutting the lower supporting frame.

Another aspect of the present disclosure provides a semiconductor device. The semiconductor device includes a substrate, a capacitor component, and a grounding electrode. The substrate includes a pad. The capacitor component is electrically connected to the pad. The grounding electrode is electrically connected to the capacitor component. The grounding electrode has a neck portion over the pad.

Another aspect of the present disclosure provides a method of manufacturing a semiconductor device. The method includes: providing a substrate having a pad; forming a first dielectric layer over the substrate; forming a sacrifice layer over the substrate; forming a second dielectric layer over the sacrifice layer; patterning the first dielectric layer, the sacrifice layer, and the second dielectric layer to form an opening over the pad, wherein the opening has a first width defined by the first dielectric layer and a second width defined by the sacrifice layer, and the first width is greater than the second width; and forming a capacitor component within the opening.

The embodiments of the present disclosure illustrate a semiconductor device including a capacitor component supported by an upper supporting frame and a lower supporting frame. The lower supporting frame defines an opening with a relatively large dimension (e.g., width or diameter) over the landing pad of the transistor, while the upper supporting frame defines an opening that keeps a proper distance between abutting capacitor electrodes. As a result, the leakage between abutting capacitor components can be prevented, while a relatively lower resistance can be achieved due to a larger contact area between the landing pad and the capacitor component. The material of the lower supporting frame can be different from that of the upper supporting frame to facilitate the formation of said opening.

The foregoing has outlined rather broadly the features and technical advantages of the present disclosure in order that the detailed description of the disclosure that follows may be better understood. Additional features and advantages of the disclosure will be described hereinafter, and form the subject of the claims of the disclosure. It should be appreciated by those skilled in the art that the conception and specific embodiment disclosed may be readily utilized as a basis for modifying or designing other structures or processes for carrying out the same purposes of the present disclosure. It should also be realized by those skilled in the art that such equivalent constructions do not depart from the spirit and scope of the disclosure as set forth in the appended claims.

### BRIEF DESCRIPTION OF THE DRAWINGS

A more complete understanding of the present disclosure may be derived by referring to the detailed description and claims when considered in connection with the Figures, where like reference numbers refer to similar elements throughout the Figures, and:

FIG. 1 is a cross-sectional view of a semiconductor device, in accordance with some embodiments of the present disclosure.

FIG. 2A is a cross-sectional view of a semiconductor device, in accordance with some embodiments of the present disclosure.

FIG. 2B is a partial enlarged view of a region R of the semiconductor device as shown in FIG. 2A, in accordance with some embodiments of the present disclosure.

FIG. 3 is a flowchart illustrating a method of manufacturing a semiconductor device, in accordance with some embodiments of the present disclosure.

FIG. 4A illustrates one or more stages of an exemplary method for manufacturing a semiconductor device according to some embodiments of the present disclosure.

FIG. 4B illustrates one or more stages of an exemplary method for manufacturing a semiconductor device according to some embodiments of the present disclosure.

FIG. 4C illustrates one or more stages of an exemplary method for manufacturing a semiconductor device according to some embodiments of the present disclosure.

FIG. 4D illustrates one or more stages of an exemplary method for manufacturing a semiconductor device according to some embodiments of the present disclosure.

FIG. 4E illustrates one or more stages of an exemplary method for manufacturing a semiconductor device according to some embodiments of the present disclosure.

FIG. 4F illustrates one or more stages of an exemplary method for manufacturing a semiconductor device according to some embodiments of the present disclosure.

FIG. 4G illustrates one or more stages of an exemplary method for manufacturing a semiconductor device according to some embodiments of the present disclosure.

FIG. 4H illustrates one or more stages of an exemplary method for manufacturing a semiconductor device according to some embodiments of the present disclosure.

FIG. 4I illustrates one or more stages of an exemplary method for manufacturing a semiconductor device according to some embodiments of the present disclosure.

FIG. 4J illustrates one or more stages of an exemplary method for manufacturing a semiconductor device according to some embodiments of the present disclosure.

FIG. 4K illustrates one or more stages of an exemplary method for manufacturing a semiconductor device according to some embodiments of the present disclosure.

FIG. 4L illustrates one or more stages of an exemplary method for manufacturing a semiconductor device according to some embodiments of the present disclosure.

FIG. 4M illustrates one or more stages of an exemplary method for manufacturing a semiconductor device according to some embodiments of the present disclosure.

FIG. 4N illustrates one or more stages of an exemplary method for manufacturing a semiconductor device according to some embodiments of the present disclosure.

FIG. 4O illustrates one or more stages of an exemplary method for manufacturing a semiconductor device according to some embodiments of the present disclosure.

FIG. 4P illustrates one or more stages of an exemplary method for manufacturing a semiconductor device according to some embodiments of the present disclosure.

### DETAILED DESCRIPTION

Embodiments, or examples, of the disclosure illustrated in the drawings are now described using specific language. It shall be understood that no limitation of the scope of the disclosure is hereby intended. Any alteration or modification of the described embodiments, and any further applications of principles described in this document, are to be considered as normally occurring to one of ordinary skill in the art to which the disclosure relates. Reference numerals may be repeated throughout the embodiments, but this does not necessarily mean that feature(s) of one embodiment apply to another embodiment, even if they share the same reference numeral.

It shall be understood that, although the terms first, second, third, etc., may be used herein to describe various elements, components, regions, layers or sections, these elements, components, regions, layers or sections are not limited by these terms. Rather, these terms are merely used to distinguish one element, component, region, layer or section from another region, layer or section. Thus, a first element, component, region, layer or section discussed below could be termed a second element, component, region, layer or section without departing from the teachings of the present inventive concept.

The terminology used herein is for the purpose of describing particular example embodiments only and is not intended to be limited to the present inventive concept. As used herein, the singular forms “a,” “an” and “the” are intended to include the plural forms as well, unless the context clearly indicates otherwise. It shall be further understood that the terms “comprises” and “comprising,” when used in this specification, point out the presence of stated features, integers, steps, operations, elements, or components, but do not preclude the presence or addition of one or more other features, integers, steps, operations, elements, components, or groups thereof.

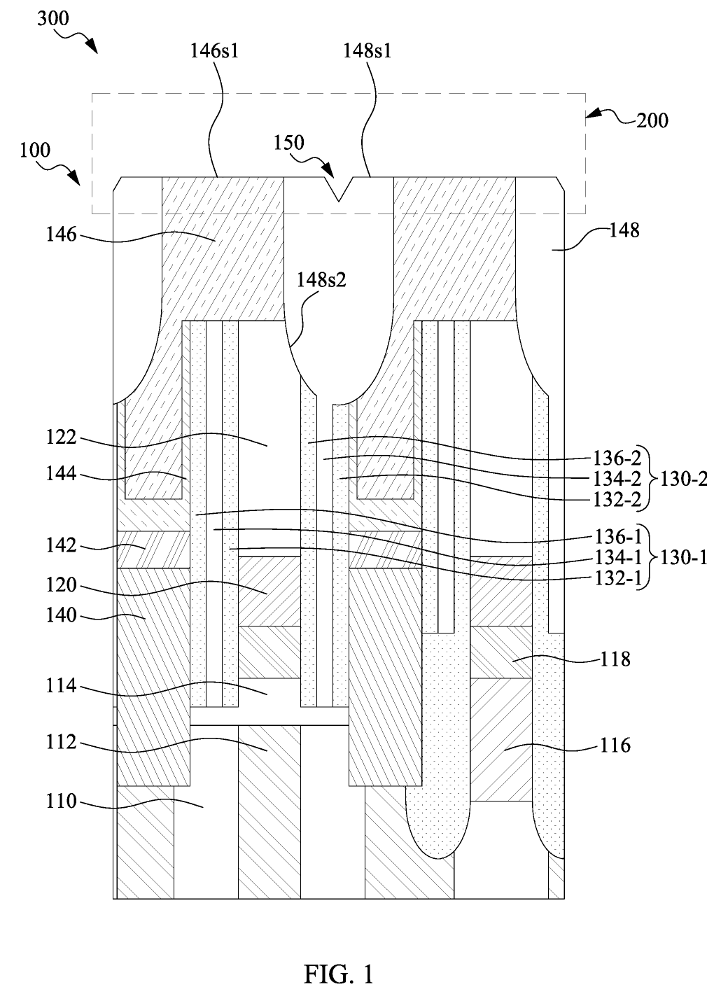

FIG. 1A is a cross-sectional view of a semiconductor device 300, in accordance with some embodiments of the present disclosure. In some embodiments, the semiconductor device 300 may include a cell region in which a memory device is formed. The memory device may include, for example, a dynamic random access memory (DRAM) device, a one-time programming (OTP) memory device, a static random access memory (SRAM) device, or other suitable memory devices. In some embodiments, a DRAM may include, for example, a transistor, a capacitor, and other components. During a read operation, a word line may be asserted, turning on the transistor. The enabled transistor allows the voltage across the capacitor to be read by a sense amplifier through a bit line. During a write operation, the data to be written may be provided on the bit line when the word line is asserted.

In some embodiments, the semiconductor device 300 may include a peripheral region (not shown) utilized to form a logic device (e.g., system-on-a-chip (SoC), central processing unit (CPU), graphics processing unit (GPU), application processor (AP), microcontroller, etc.), a radio frequency (RF) device, a sensor device, a micro-electro-mechanical-system (MEMS) device, a signal processing device (e.g., digital signal processing (DSP) device)), a front-end device (e.g., analog front-end (AFE) devices) or other devices.

The semiconductor device 300 may include a carrier 100 and a device disposed over the carrier 100. The carrier 100 may include a switch (e.g., transistor) configured to turn on or turn off a capacitor(s) within the device 200.

The semiconductor device 300 may include a substrate 110. The substrate 110 may be a semiconductor substrate, such as a bulk semiconductor, a semiconductor-on-insulator (SOI) substrate, or the like. The substrate 110 may include an elementary semiconductor including silicon or germanium in a single crystal form, a polycrystalline form, or an amorphous form; a compound semiconductor material including at least one of silicon carbide, gallium arsenide, gallium phosphide, indium phosphide, indium arsenide, and indium antimonide; an alloy semiconductor material including at least one of SiGe, GaAsP, AlInAs, AlGaAs, GaInAs, GaInP, and GaInAsP; any other suitable materials; or a combination thereof. In some embodiments, the alloy semiconductor substrate may be a SiGe alloy with a gradient Ge feature in which the Si and Ge composition changes from one ratio at one location to another ratio at another location of the gradient SiGe feature. In another embodiment, the SiGe alloy is formed over a silicon substrate. In some embodiments, a SiGe alloy may be mechanically strained by another material in contact with the SiGe alloy. In some embodiments, the substrate 110 may have a multilayered structure, or the substrate 110 may include a multilayered compound semiconductor structure.

In some embodiments, the carrier 100 may include a plurality of active areas. The active area may function as, for example, a channel for electrical connection.

In some embodiments, the carrier 100 may include isolation structures 112. In some embodiments, the plurality of active areas may be separated by the isolation structures 112. In some embodiments, the isolation spacer 112 may be embedded in the substrate 110. In some embodiments, the isolation spacer 112 may include, for example, silicon oxide (SiO₂), silicon nitride (Si₃N₄), silicon oxynitride (N₂OSi₂), silicon nitride oxide (N₂OSi₂), or other suitable materials. In some embodiments, a portion of the substrate 110 may be removed to form trenches, and a dielectric material(s) is filled into the trenches to form the isolation structures 112.

In some embodiments, the carrier 100 may include a dielectric layer 114. The dielectric layer 114 may be disposed on the substrate 110. In some embodiments, the dielectric layer 114 may cover a portion of the isolation spacer 112. In some embodiments, the dielectric layer 114 may include, for example, silicon oxide (SiO₂), silicon nitride (Si₃N₄), silicon oxynitride (N₂OSi₂), silicon nitride oxide (N₂OSi₂), a high-k material or combinations thereof. Examples of the high-k material include a dielectric material having a dielectric constant exceeding that of silicon dioxide (SiO₂), or a dielectric material having a dielectric constant higher than about 3.9. In some embodiments, the dielectric layer 114 may include at least one metallic element, such as hafnium oxide (HfO₂), silicon doped hafnium oxide (HSO), lanthanum oxide (La₂O₃), lanthanum aluminum oxide (LaAlO₃), zirconium orthosilicate (ZrSiO₄), aluminum oxide (Al₂O₃) or combinations thereof.

In some embodiments, the carrier 100 may include a bit line contact 116. In some embodiments, the bit line contact 116 may be disposed on the active area of the 100. The bit line contact 116 may include metal, such as tungsten (W), copper (Cu), ruthenium (Ru), iridium (Ir), nickel (Ni), osmium (Os), rhodium (Rh), aluminum (Al), molybdenum (Mo), cobalt (Co), silver (Ag), gold (Au), alloys combinations thereof or any metallic material with suitable resistance and gap-fill capability.

In some embodiments, the carrier 100 may include bit line stacks 118. In some embodiments, the bit line stack 118 may include a multilayered structure. In some embodiments, a portion of the bit line stacks 118 may be disposed on the bit line contact 116. A portion of the bit line stacks 118 may be spaced apart from the substrate 110 by the dielectric layer 114. In some embodiments, a portion of the bit line stacks 118 may be in contact with the bit line contact 116. In some embodiments, a portion of the bit line stacks 118 may be electrically connected to the bit line contact 116. In some embodiments, a portion of the bit line stacks 118 may be disposed on the dielectric layer 114. In some embodiments, a portion of the bit line stacks 118 may be in contact with the dielectric layer 114. The bit line stack 118 may include titanium (Ti), tantalum (Ta), titanium nitride (TiN), copper (Cu), tantalum nitride (TaN), manganese nitride (MnN) or a combination thereof.

In some embodiments, the carrier 100 may include bit lines 120. In some embodiments, each of the bit lines 120 may be disposed on the bit line stack 118. In some embodiments, a portion of the bit lines 120 may be disposed on the bit line contact 116. In some embodiments, a portion of the bit lines 120 may be electrically connected to the bit line contact 116. In some embodiments, a portion of the bit lines 120 may be disposed on the dielectric layer 114. The bit line 120 may include metal, such as tungsten (W), copper (Cu), ruthenium (Ru), iridium (Ir), nickel (Ni), osmium (Os), rhodium (Rh), aluminum (Al), molybdenum (Mo), cobalt (Co), silver (Ag), gold (Au), alloys thereof, or combinations thereof.

In some embodiments, the carrier 100 may include dielectric layers 122. In some embodiments, each of the dielectric layers 122 may be disposed on the bit line 120. In some embodiments, the dielectric layer 122 may include, for example, silicon oxide, silicon nitride, silicon oxynitride, silicon nitride oxide, a high-k material or combinations thereof.

In some embodiments, the carrier 100 may include isolation spacers 130-1 and 130-2. The isolation spacer 130-1 may be disposed on a first side of the bit line 120. The isolation spacer 130-2 may be disposed on a second side, opposite to the first side in a cross-sectional view, of the bit line 120. It should be noted that although FIG. 1A illustrates the isolation spacers 130-1 and 130-2 separated in a cross-section, the isolation spacers 130-1 and 130-2 may be a part of an integral (or monolithic) structure, with said integral structure having a circular profile, an elliptical profile, or the like from a top view.

In some embodiments, the isolation spacer 130-1 may have a dielectric layer 132-1, an air gap 134-1, and a dielectric layer 136-1. In some embodiments, the isolation spacer 130-2 may have a dielectric layer 132-2, an air gap 134-2, and a dielectric layer 136-2. In some embodiments, the dielectric layers 132-1 and 132-2 may be formed on the sidewalls of the bit line contact 116, the bit line stack 118, the bit line 120, and the dielectric layer 122. For example, the dielectric layer 132-1 may be formed on the first side of the bit line 120, and the dielectric layer 132-2 may be formed on the second side of the bit line 120. In some embodiments, the dielectric layer 132-1 may be in contact with the first side of the bit line 120. In some embodiments, the dielectric layer 132-2 may be in contact with the second side of the bit line 120. In some embodiments, a portion of the dielectric layer 132-1 may be embedded in the substrate 110. In some embodiments, a portion of the dielectric layer 132-2 may be embedded in the substrate 110.

In some embodiments, the air gap 134-1 may be spaced apart from the bit line 120 by the dielectric layer 132-1. In some embodiments, the air gap 134-2 may be spaced apart from the bit line 120 by the dielectric layer 132-2. In some embodiments, the air gap 134-1 may be disposed between the dielectric layers 132-1 and 136-1. In some embodiments, the air gap 134-2 may be disposed between the dielectric layers 132-2 and 136-2. In some embodiments, the length of the air gap 134-2 may be less than that of the air gap 134-1. Although FIG. 1 illustrates that the air gap 134-1 is spaced apart from or distinct from the air gap 134-2, the air gap 134-1 may be connected to the air gap 134-2 in other embodiments.

In some embodiments, the dielectric layer 136-1 may be disposed on the dielectric layer 132-1. In some embodiments, the dielectric layer 136-2 may be disposed on the dielectric layer 132-2. In some embodiments, each of the dielectric layers 132-1, 132-2, 136-1 and/or 136-2 may include, for example, silicon oxide, silicon nitride, silicon oxynitride, silicon nitride oxide, a high-k material or combinations thereof. Although FIG. 1A illustrates that the dielectric layer 132-1 is spaced apart from the dielectric layer 136-1, the dielectric layer 132-1 may be connected to the dielectric layer 136-1 in other embodiments.

In some embodiments, the air gaps 134-1 and 134-2 may be replaced by a dielectric material(s) with a suitable dielectric constant.

In some embodiments, the carrier 100 may include a capacitor contact 140. In some embodiments, a portion of the capacitor contact 140 may be in contact with the substrate 100. In some embodiments, the capacitor contact 140 may be formed between two bit lines 120. In some embodiments, the capacitor contact 140 may be formed between the isolation spacers 130-1 and 130-2. In some embodiments, the capacitor contact 140 may be formed between the dielectric layers 136-1 and 136-2. The capacitor contact 140 may include metal, such as tungsten (W), copper (Cu), ruthenium (Ru), iridium (Ir), nickel (Ni), osmium (Os), rhodium (Rh), aluminum (Al), molybdenum (Mo), cobalt (Co), alloys thereof, combinations thereof or any metallic material.

In some embodiments, the carrier 100 may include a conductive stack structure 142. The conductive stack structure 142 may include a multilayered structure. In some embodiments, the conductive stack structure 142 may be formed on a top surface of the capacitor contact 140. The conductive stack structure 142 may be disposed between the isolation spacers 130-1 and 130-2. In some embodiments, the conductive stack structure 142 may include metal silicide, such as, cobalt silicide (CoSi) or other suitable materials.

In some embodiments, the carrier 100 may include a liner 144. In some embodiments, the liner 144 may be formed on a top surface of the capacitor contact 140. In some embodiments, the liner 144 may be disposed on the sidewalls of the isolation spacers 130-1 and 130-2. In some embodiments, the liner 144 may include metal nitride, such as titanium nitride (TiN), aluminum nitride (AlN), hafnium nitride (HfN), lanthanum nitride (LaN), scandium nitride (ScN), or other suitable materials.

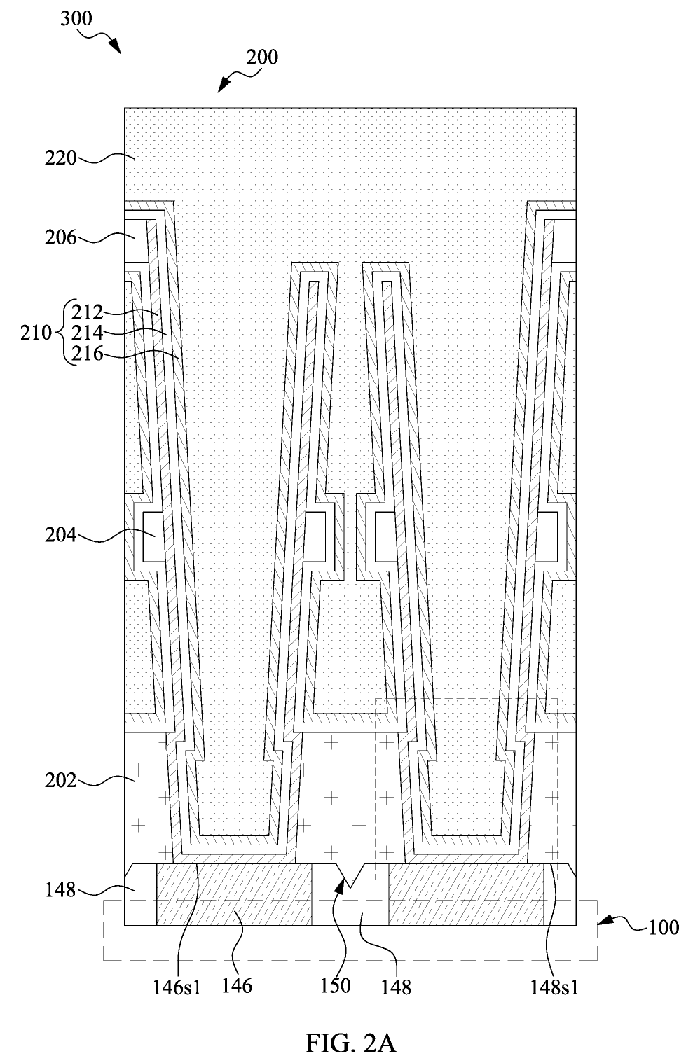

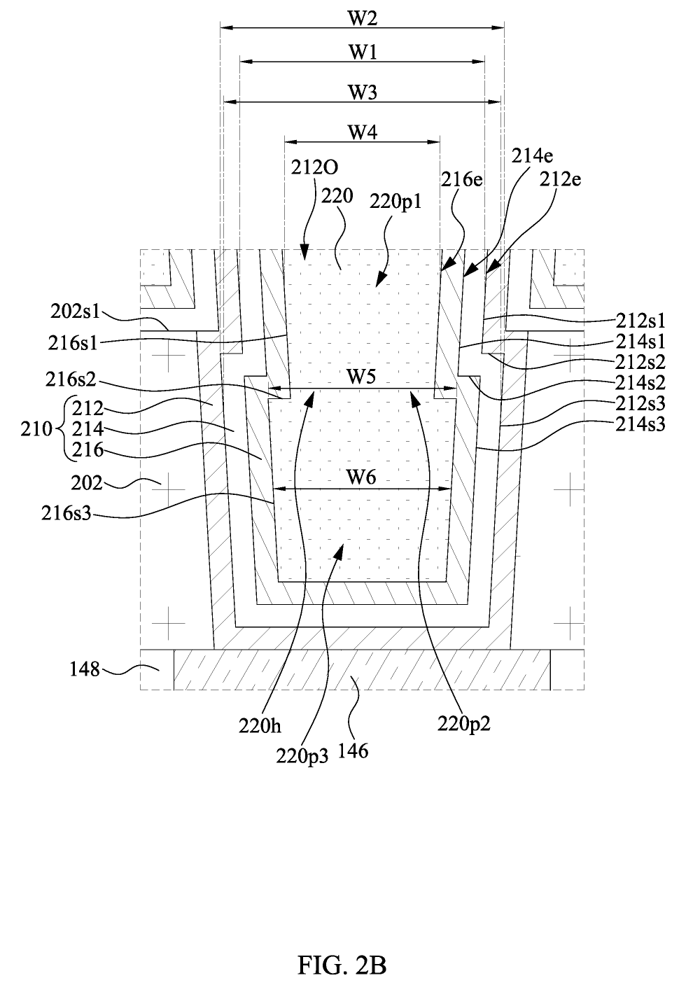

In some embodiments, the carrier 100 may include pads 146 (or landing pads). Each of the pads 146 may be configured to electrically connect a capacitor structure (shown in FIG. 2A). In some embodiments, the pad 146 may be formed on the liner 144. In some embodiments, the pad 146 may be formed between the isolation spacers 130-1 and 130-2. In some embodiments, the pad 146 may cover a top surface the isolation spacer 130-1. In some embodiments, the pad 146 may cover a top surface of the dielectric layer 132-1. In some embodiments, the pad 146 may cover a top surface of the dielectric layer 136-1. In some embodiments, the air gap 134-1 may be covered by the pad 146. In some embodiments, the air gap 134-2 may be free from vertically overlapping the pad 146. In some embodiments, the pad 146 may cover a top surface the isolation spacer 130-2. In some embodiments, a portion of the pad 146 may be surrounded by the liner 144. In some embodiments, the pad 146 may cover a top surface of the dielectric layer 122. In some embodiments, the pad 146 may include an upper portion over the dielectric layer 122 and a lower portion between adjacent dielectric layers 122. In some embodiments, the pad 146 may include metal, such as tungsten (W), copper (Cu), ruthenium (Ru), iridium (Ir), nickel (Ni), osmium (Os), rhodium (Rh), aluminum (Al), molybdenum (Mo), cobalt (Co), silver (Ag), gold (Au), alloys thereof, or combinations thereof.

In some embodiments, the carrier 100 may include a passivation layer 148. In some embodiments, the passivation layer 148 may cover the isolation spacer 130-2. In some embodiments, the air gap 134-2 may be covered by the passivation layer 148. In some embodiments, the passivation layer 148 may be spaced apart from the isolation spacer 130-1 by the pad 146. The passivation layer 148 may have a surface 148s1 and a surface 148s2. The surface 148s1 (or a top surface) may face away from the carrier 100. The surface 148s2 (or a lateral surface) may cover or in contact with the dielectric layer 122. In some embodiments, the passivation layer 148 may include silicon nitride, silicon oxide, or other suitable materials. In some embodiments, the passivation layer 148 may define a recess 150, which is recessed from the surface 148s1. In some embodiments, the surface 148s1 of the passivation layer 148 may be substantially aligned or coplanar with a surface 146s1 (or a top surface) of the pad 146.

Although not shown in FIG. 1, the carrier 100 may include more components, such as word lines and/or other conductive and non-conductive layers, based on the design requirements.

In some embodiments, the carrier 100 may include a device 200. The device 200 may be disposed on or over the pad 146. The device 200 may include a capacitor component electrically connected to the pad 146. The transistors shown in FIG. 1 may be configured to switch on or off the capacitor component within the device 200.

FIG. 2A and FIG. 2B illustrate the device 200 in detail, wherein FIG. 2B is a partial enlarged view of the device 200.

The device 200 may be disposed over the carrier 100 to cover the pad 146. In some embodiments, the device 200 may include a supporting frame 202, a supporting frame 204, and a supporting frame 206 which are located at different elevations and configured to support a capacitor component 210.

In some embodiments, the supporting frame 202 (or a lower supporting frame) may be disposed on or over the passivation layer 148. In some embodiments, the supporting frame 202 may fill the recess 150 of the passivation layer 148. In some embodiments, the supporting frame 202 may cover a portion of the pad 146. In some embodiments, the supporting frame 202 may be in contact with the pad 146. In some embodiments, the supporting frame 202 may be configured to support the capacitor component 210. The supporting frame 202 may be utilized to define the patterns of the capacitor component 210. In some embodiments, the material of the supporting frame 202 may be different from that of the passivation layer 148. In some embodiments, the hardness of the supporting frame 202 may be greater than that of the passivation layer 148. In some embodiments, the supporting frame 202 may include carbide. In some embodiments, the supporting frame 202 may include silicon carbide, silicon oxycarbide, boron carbide, or metal carbide (e.g., aluminum carbide, tungsten carbide, titanium carbide, calcium carbide, or other suitable materials).

In some embodiments, the supporting frame 204 (or a middle supporting frame) may be disposed on or over the supporting frame 202. In some embodiments, the supporting frame 204 may be spaced apart from the supporting frame 202. In some embodiments, the supporting frame 204 may be configured to support the capacitor component 210. The supporting frame 204 may be utilized to define the patterns of the capacitor component 210. In some embodiments, the material of the supporting frame 204 may be different from that of the supporting frame 202. In some embodiments, the hardness of the supporting frame 204 may be less than that of the supporting frame 202. In some embodiments, the supporting frame 204 may include silicon nitride, silicon oxide, silicon oxynitride, silicon nitride oxide, or other suitable materials.

In some embodiments, the supporting frame 206 (or an upper supporting frame) may be disposed on or over the supporting frame 204. In some embodiments, the supporting frame 206 may be spaced apart from the supporting frame 204. In some embodiments, the supporting frame 206 may be configured to support the capacitor component 210. The supporting frame 206 may be utilized to define the patterns of the capacitor component 210. In some embodiments, the material of the supporting frame 206 may be different from that of the supporting frame 202. In some embodiments, the hardness of the supporting frame 206 may be less than that of the supporting frame 202. In some embodiments, the supporting frame 206 may include silicon nitride, silicon oxide, silicon oxynitride, silicon nitride oxide, or other suitable materials.

The capacitor component 210 may be disposed on or over the carrier 100. In some embodiments, the capacitor component 210 may be electrically connected to the pad 146. In some embodiments, the capacitor component 210 may be supported by and in contact with the supporting frame 202, supporting frame 204, and supporting frame 206. In some embodiments, the capacitor component 210 may include a lower electrode 212, a capacitor dielectric 214, and an upper electrode 216.

In some embodiments, the lower electrode 212 may be disposed on the carrier 100. In some embodiments, the lower electrode 212 may be disposed on and electrically connected to the pad 146. In some embodiments, the lower electrode 212 may be disposed within the opening defined by the supporting frame 202, supporting frame 204, and supporting frame 206. In some embodiments, the lower electrode 212 may be disposed on or in contact with the lateral surface of the supporting frame 202. In some embodiments, the lower electrode 212 may be disposed on or in contact with the lateral surface of the supporting frame 204. In some embodiments, the lower electrode 212 may be disposed on or in contact with the lateral surface of the supporting frame 206. The lower electrode 212 may include conductive material(s), conductive metal nitride (e.g., titanium nitride, tantalum nitride, tungsten nitride, or the like), metal (e.g., copper, tungsten, ruthenium, iridium, nickel, osmium, rhodium, aluminum, molybdenum, cobalt, or the like), and conductive metal oxide (e.g., iridium oxide or the like).

The capacitor dielectric 214 may be conformally disposed on the lower electrode 212. In some embodiments, the capacitor dielectric 214 may be disposed on or in contact with the upper surface of the supporting frame 202. In some embodiments, the capacitor dielectric 214 may be disposed on or in contact with the upper surfaces of the supporting frame 204 and supporting frame 206. In some embodiments, the capacitor dielectric 214 may be disposed on or in contact with the lower surfaces of the supporting frame 204 and supporting frame 206. In some embodiments, the capacitor dielectric 214 may be disposed on or in contact with the lateral surfaces of the supporting frame 204 and supporting frame 206. The capacitor dielectric 214 may include silicon oxide, tungsten oxide, copper oxide, aluminum oxide, hafnium oxide, or the like.

In some embodiments, the upper electrode 216 may be disposed on the capacitor dielectric 214. The upper electrode 216 may be spaced apart from the lower electrode 212 by the capacitor dielectric 214. The upper electrode 216 may include conductive material(s), conductive metal nitride (e.g., titanium nitride, tantalum nitride, tungsten nitride, or the like), metal (e.g., copper, tungsten, ruthenium, iridium, nickel, osmium, rhodium, aluminum, molybdenum, cobalt, or the like), and conductive metal oxide (e.g., iridium oxide or the like). In some embodiments, each of the supporting frame 202, supporting frame 204, and supporting frame 206 may define a ring profile, from a top view, to accommodate the capacitor component 210.

In some embodiments, the device 200 further includes a grounding electrode 220. In some embodiments, the grounding electrode 220 may be electrically connected to ground. In some embodiments, the grounding electrode 220 may be electrically connected to the capacitor component 210. In some embodiments, the grounding electrode 220 may be electrically connected to and in contact with the upper electrode 216. In some embodiments, the grounding electrode 220 may include doped polysilicon or other suitable materials. In some embodiments, the grounding electrode 220 may have a portion tapered toward the carrier 100. In some embodiments, the tapered portion of the grounding electrode 220 may be directly over the pad 146.

Referring to FIG. 2B, in some embodiments, the lower electrode 212 may have a sidewall 212e (or an inner sidewall), spaced apart from the supporting frame 202, which is noncontinuous. For example, the sidewall 212e may include a surface 212s1, a surface 212s2, and a surface 212s3. The surface 212s1 is at an elevation higher than or equal to the surface 212s2. The surface 212s2 is at an elevation higher than or equal to the surface 212s3. The surface 212s2 may extend between the surfaces 212s1 and 212s3. In some embodiments, the slope of the surface 212s1 may be different from that of the surface 212s2. In some embodiments, the slope of the surface 212s2 may be different from that of the surface 212s3. In some embodiments, the sidewall 212e may extend outwardly abutting the surface 202s1 of the supporting frame 202. For example, the sidewall 212e may include the surface 212s2 extending horizontally, thereby enlarges an opening 212O defined by the lower electrode.

The opening 212O may be configured to accommodate the capacitor dielectric 214, the upper electrode 216, and the grounding electrode 220. The opening 212O may be directly over the pad 146. The opening 212O may have a width W1 at the elevation the same as that of the surface 212s1. The opening 212O may have a width W2 at the elevation the same as that of the surface 212s2. The opening 212O may have a width W3 at the elevation the same as that of surface 212s3. In some embodiments, the width W1 may be less than the width W2. In some embodiments, the width W3 may be less than the width W2.

In some embodiments, the capacitor dielectric 214 may have a sidewall 214e which is noncontinuous. For example, the sidewall 212e may include a surface 214s1, a surface 214s2, and a surface 214s3. The surface 214s1 is at an elevation higher than the surface 202s1 of the supporting frame 202. The surface 214s2 may extend between the surfaces 214s1 and 214s3. The surface 214s3 is at an elevation below the surface 202s1 and abutting the upper surface of the pad 146 of the carrier 100. In some embodiments, the slope of the surface 214s1 may be different from that of the surface 214s2. In some embodiments, the slope of the surface 214s2 may be different from that of the surface 214s3. In some embodiments, the sidewall 214e may extend outwardly abutting the surface 202s1 of the supporting frame 202. For example, the sidewall 214e may include the surface 214s2 extending horizontally, thereby enlarges an opening defined by the capacitor dielectric 214.

In some embodiments, the upper electrode 216 may have a sidewall 216e which is noncontinuous. For example, the sidewall 216e may include a surface 216s1, a surface 216s2, and a surface 216s3. The surface 216s1 is at an elevation higher than the surface 202s1 of the supporting frame 202. The surface 216s2 may extend between the surfaces 216s1 and 216s3. The surface 216s3 is at an elevation below the surface 202s1 and abutting the upper surface of the pad 146 of the carrier 100. In some embodiments, the slope of the surface 216s1 may be different from that of the surface 216s2. In some embodiments, the slope of the surface 216s2 may be different from that of the surface 216s3. In some embodiments, the sidewall 216e may extend outwardly abutting the surface 202s1 of the supporting frame 202. For example, the sidewall 216e may include the surface 216s2 extending horizontally, thereby enlarges an opening defined by the upper electrode 216.

In some embodiments, the grounding electrode 220 may include a neck portion 220h. In some embodiments, the neck portion 220h may be directly over the pad 146. The neck portion 220h may have a relatively small dimension (e.g., width or diameter) than its abutting portion. The grounding electrode 220 may have a portion 220p1, portion 220p2, and a portion 220p3. The portion 220p2 may be defined as the narrowest portion of the grounding electrode 220 in the cross-sectional view. The portion 220p1 is at an elevation higher than the portion 220p2. The portion 220p3 is at an elevation below the portion 220p2 and abutting the upper surface of the pad 146 of the carrier 100.

In some embodiments, the grounding electrode 220 may extend outwardly abutting the surface 202s1 of the supporting frame 202. The portion 220p1 may have a width W4. The portion 220p2 may have a width W5. The portion 220p6 may have a width W6. In some embodiments, the width W4 may be less than the width W5. In some embodiments, the width W6 may be less than the width W5. In some embodiments, the width W6 may be less than the width W4.

In this embodiment, the lower supporting frame (e.g., the supporting frame 202) defines an opening with a relatively large dimension (e.g., width or diameter) over the landing pad (e.g., the pad 146), while the upper supporting frame (e.g., the supporting frame 206) may define an opening that keeps a proper distance between abutting capacitor electrodes (e.g., the lower electrode 212). As a result, the leakage of the capacitor components (e.g., the capacitor component 210) can be prevented, while a relatively lower resistance can be achieved due to a larger contact area between the landing pad and the capacitor component. Further, the material of the lower supporting frame can be different from that of the upper supporting frame to facilitate the formation of said opening.

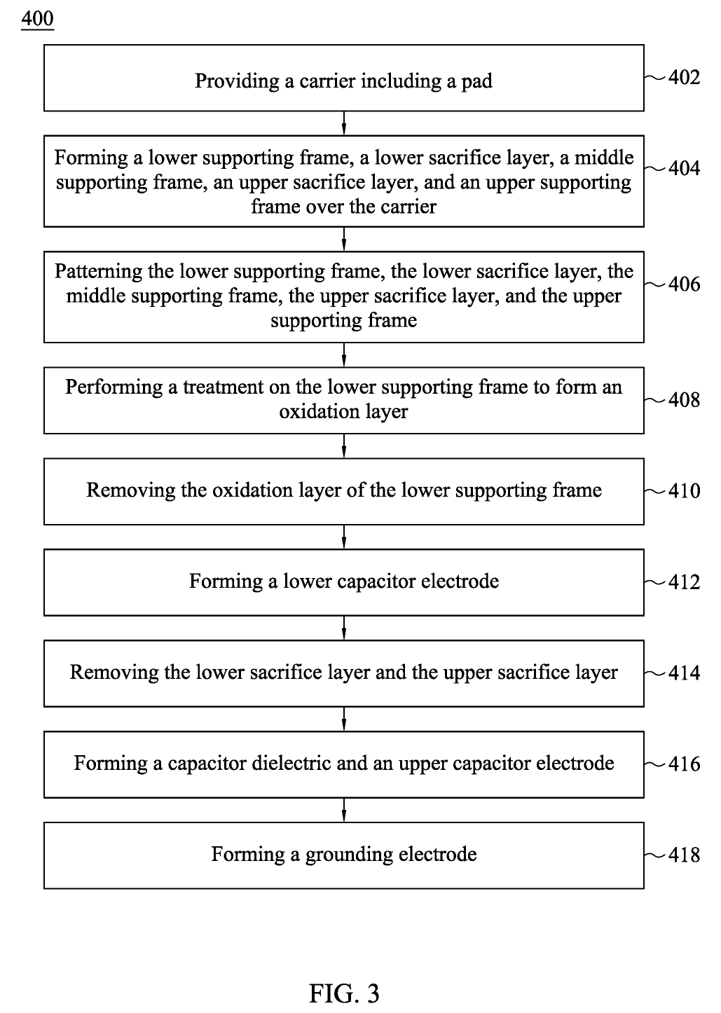

FIG. 3 is a flowchart illustrating a method 400 of manufacturing a semiconductor device, in accordance with some embodiments of the present disclosure.

The method 400 may begin with an operation 402 in which a carrier is provided. The carrier may include a pad electrically connected to a transistor. The carrier may include a passivation layer surrounding the pad.

The method 400 may continue with an operation 404 in which a lower supporting frame, a lower sacrifice layer, a middle supporting frame, an upper sacrifice layer, and an upper supporting frame are formed on the carrier. The material of the lower supporting frame may be different from that of the middle supporting frame and the upper supporting frame. The lower supporting frame may include carbide, which may include silicon carbide, silicon oxycarbide, boron carbide, or metal carbide (e.g., aluminum carbide, tungsten carbide, titanium carbide, calcium carbide, or other suitable materials).

The method 400 may continue with an operation 406 in which the lower supporting frame, the lower sacrifice layer, the middle supporting frame, the upper sacrifice layer, and the upper supporting frame are patterned to define an opening. The pad may be exposed by the opening.

The method 400 may continue with an operation 408 in which a treatment is performed on the lower supporting frame to form an oxidation layer (or oxidized layer or oxidized portion or treated portion). The lower supporting frame may be reactive to the etchant(s) or gas(s) used in an etching technique to remove the mask which is configure to pattern the lower supporting frame, the lower sacrifice layer, the middle supporting frame, the upper sacrifice layer, and the upper supporting frame. The lower supporting frame may be oxidized. Oxidized lower supporting frame may be formed on the lateral surface of the lower supporting frame. The oxidized lower supporting frame may include oxycarbide, boron oxycarbide, and/or metal oxycarbide (e.g., aluminum oxycarbide, tungsten oxycarbide, titanium oxycarbide, calcium oxycarbide, or other suitable materials), or a combination thereof.

The method 400 may continue with an operation 410 in which the oxidation layer of the lower supporting frame may be removed. As a result, the sidewall of the lower supporting frame may be recessed from the sidewall of the sacrifice layer. The etchant(s) may include diluted hydrofluoric acid or other suitable etchants.

The method 400 may continue with an operation 412 in which a lower capacitor electrode (or a lower electrode) may be formed within the opening defined by the lower supporting frame, the lower sacrifice layer, the middle supporting frame, the upper sacrifice layer, and the upper supporting frame.

The method 400 may continue with an operation 414 in which the lower sacrifice layer and the upper sacrifice layer are removed.

The method 400 may continue with an operation 416 in which a capacitor dielectric and an upper capacitor electrode are formed on the lower capacitor electrode to define a capacitor component.

The method 400 may continue with an operation 418 in which a grounding electrode is formed on the capacitor component. As a result, a semiconductor device may be produced.

The method 400 is merely an example, and is not intended to limit the present disclosure beyond what is explicitly recited in the claims. Additional operations can be provided before, during, or after each operations of the method 400, and some operations described can be replaced, eliminated, or reordered for additional embodiments of the method. In some embodiments, the method 400 can include further operations not depicted in FIG. 3. In some embodiments, the method 400 can include one or more operations depicted in FIG. 3.

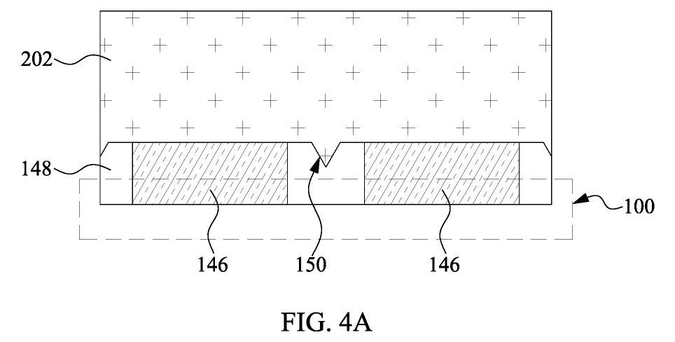

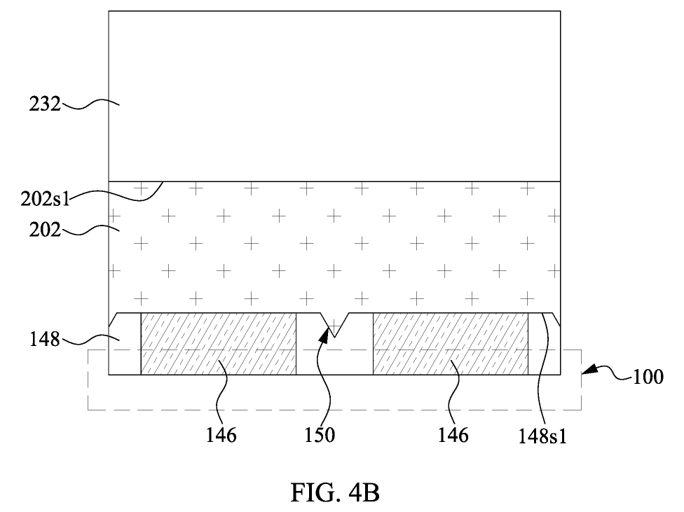

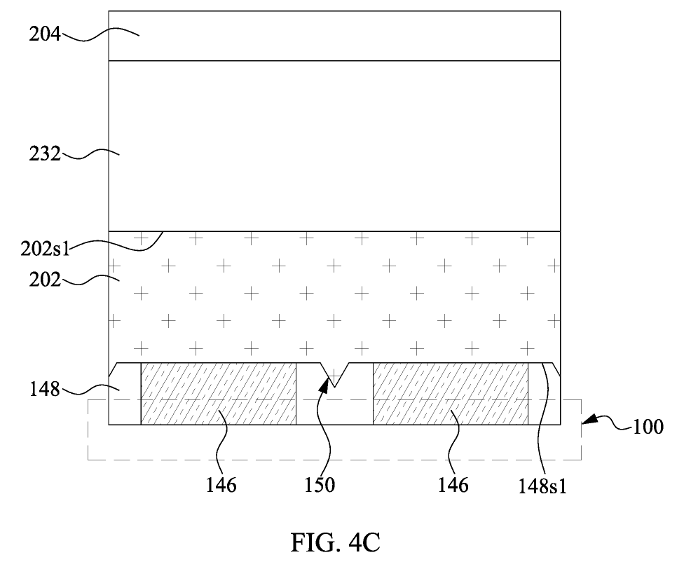

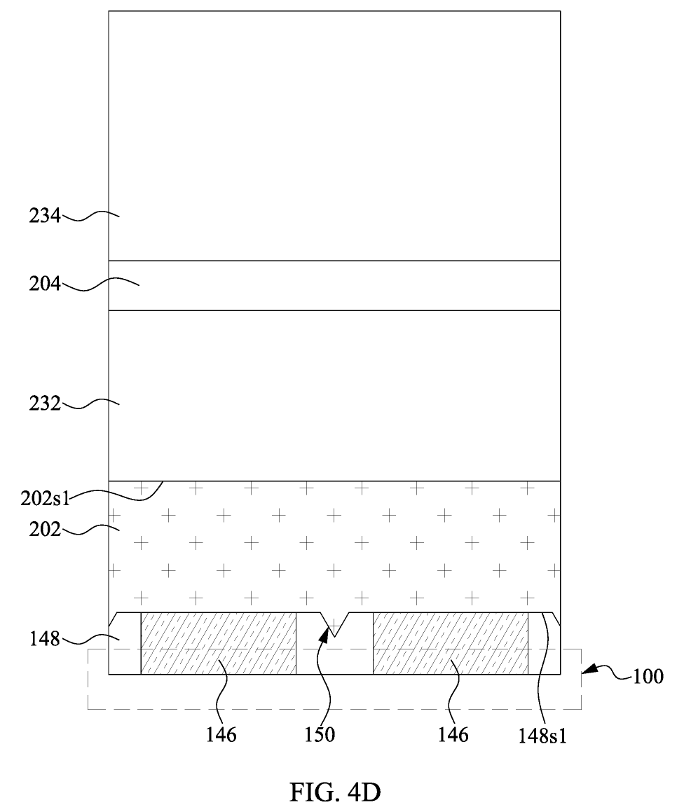

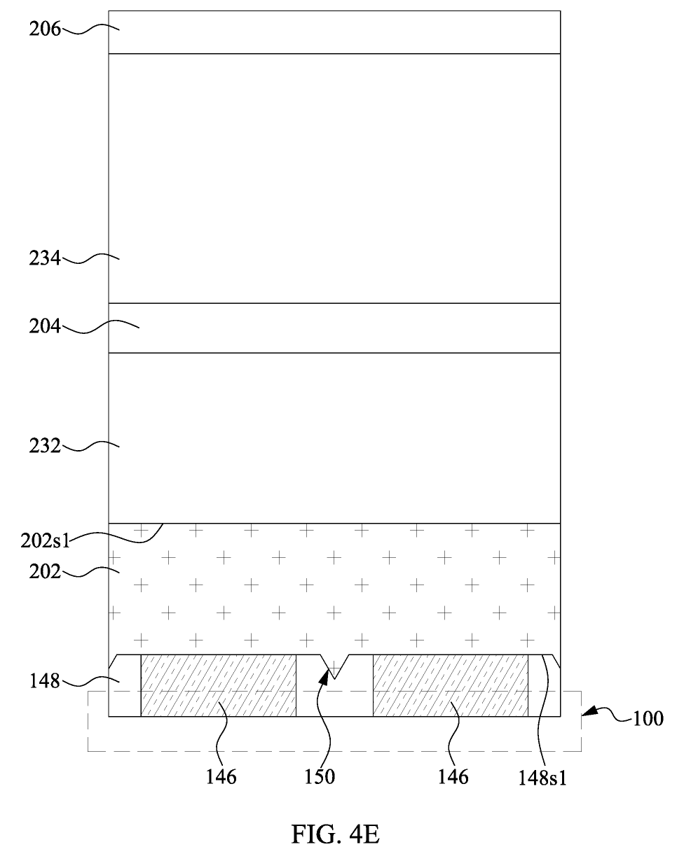

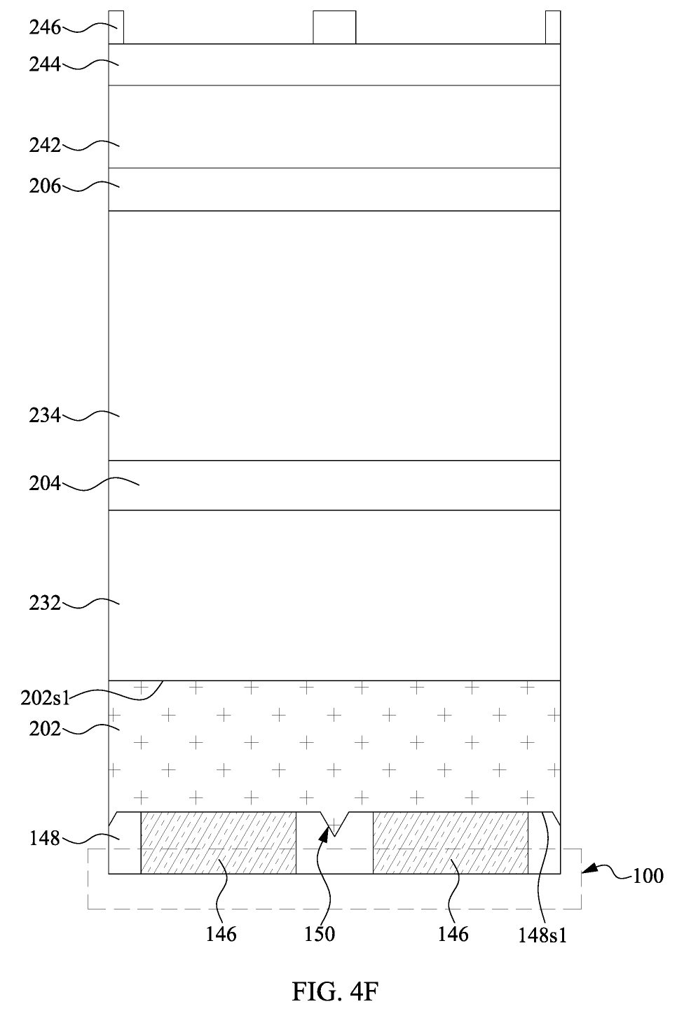

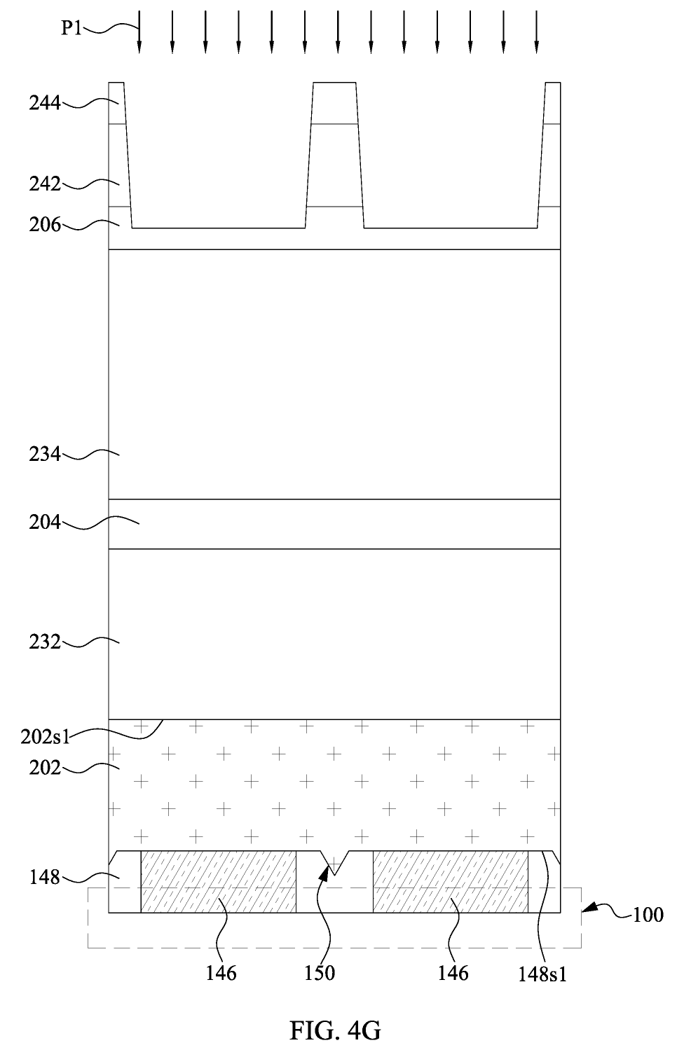

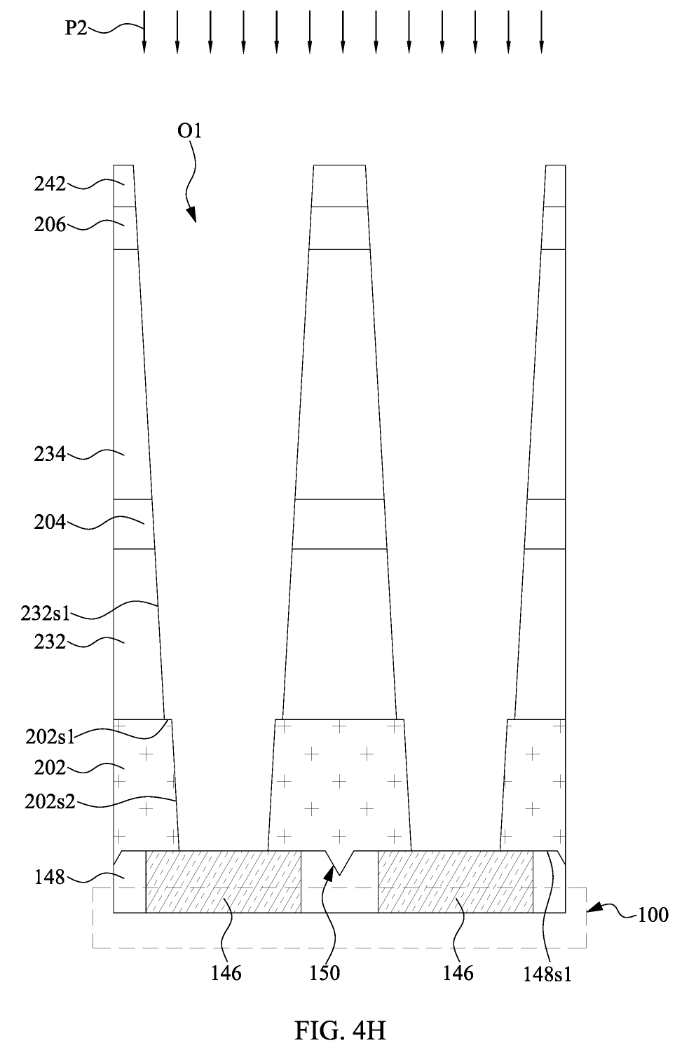

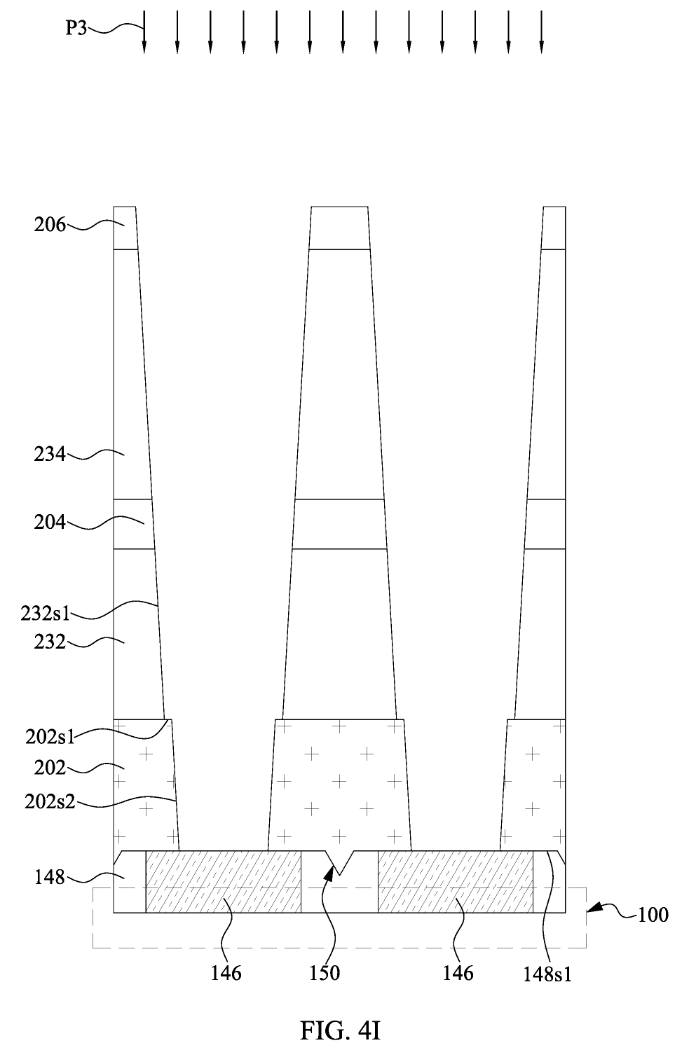

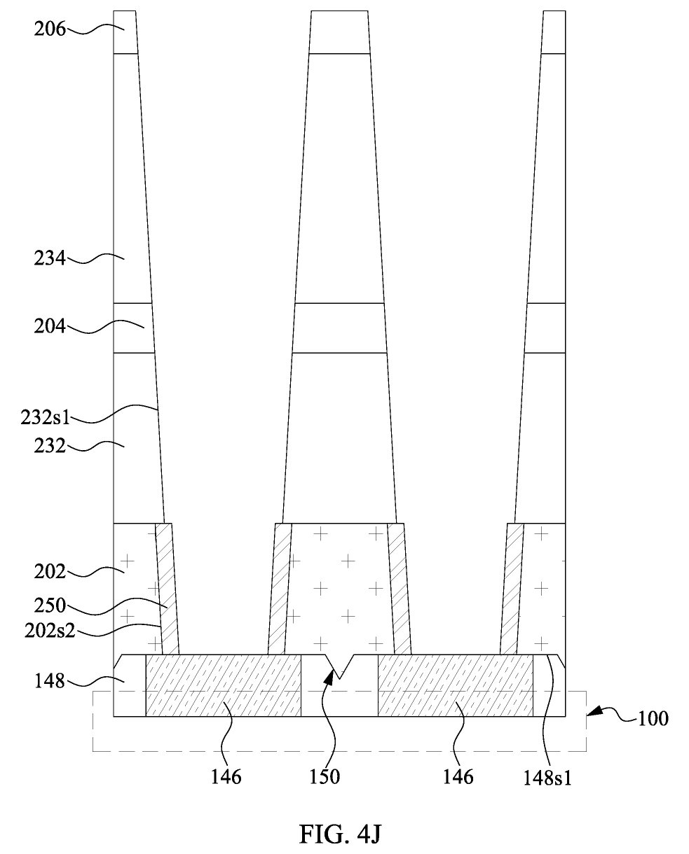

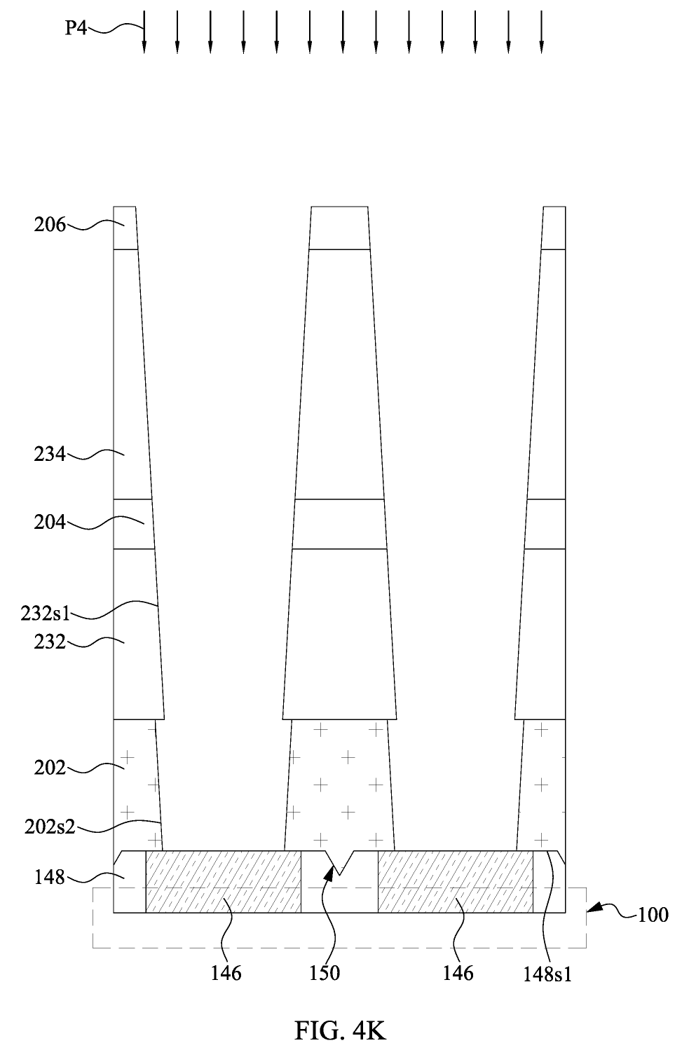

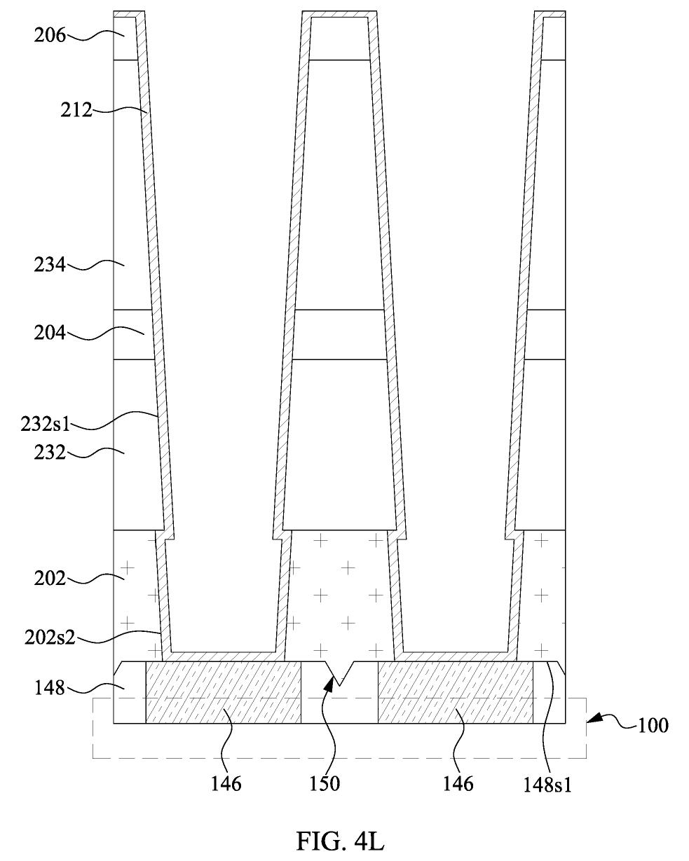

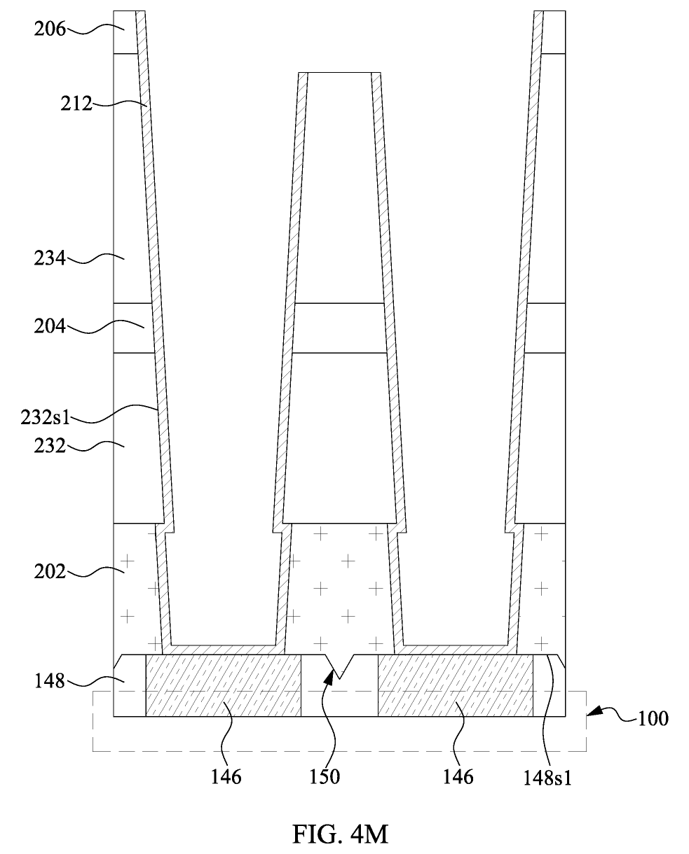

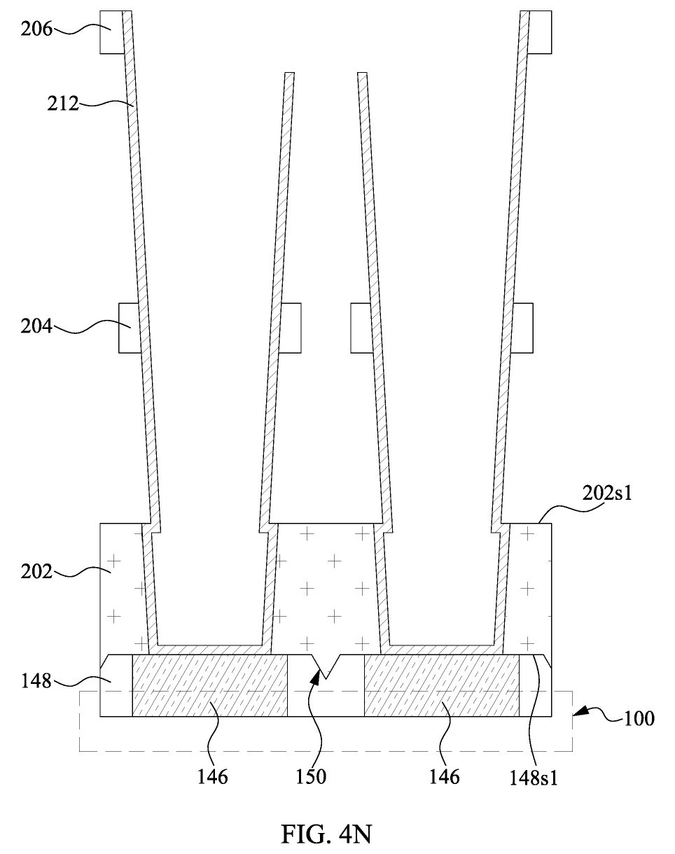

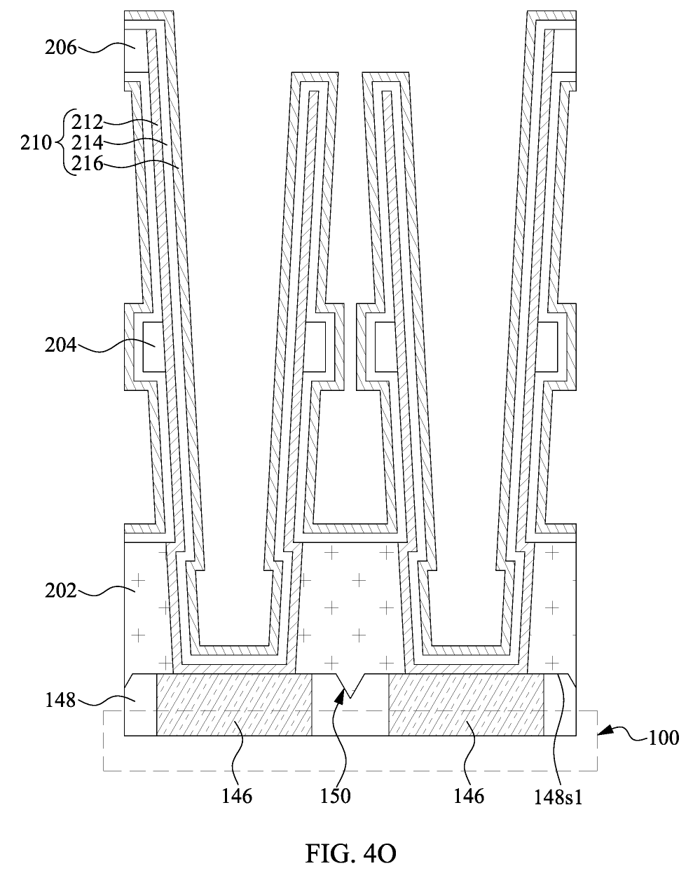

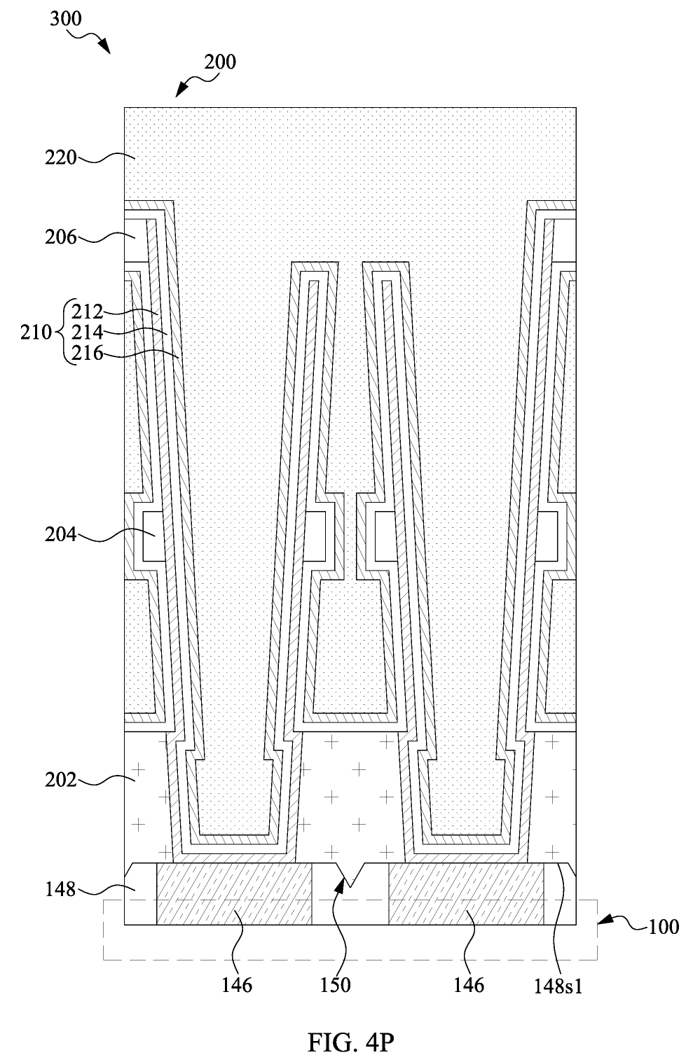

FIGS. 4A to FIG. 4P illustrates one or more stages of an exemplary method for manufacturing a semiconductor device according to some embodiments of the present disclosure.

Referring to FIG. 4A, the carrier 100 may be provided. The carrier 100 may include the pads 146 and the passivation layer 148 surrounding the pads 146. In some embodiments, the passivation layer 148 may include the recess 150 recessed from the surface 148s1. In some embodiments, the supporting frame 202 may be formed on or over the pad 146. In some embodiments, the supporting frame 202 may be formed on or over the passivation layer 148. In some embodiments, the supporting frame 202 may fill the recess 150. In some embodiments, the supporting frame 202 may be formed by, for example, chemical vapor deposition (CVD), atomic layer deposition (ALD), physical vapor deposition (PVD), low-pressure chemical vapor deposition (LPCVD), flowable chemical vapor deposition (FCVD), or other suitable process. FIG. 4A illustrates a stage corresponding the operation 402 as shown in FIG. 3.

Referring to FIG. 4B, a sacrifice layer 232 (or a lower sacrifice layer) may be formed on or over the supporting frame 202. The sacrifice layer 232 may be removed in subsequent processes. In some embodiments, the material of the sacrifice layer 232 may be different from that of the supporting frame 202. In some embodiments, the sacrifice layer 232 may include silicon oxide, silicon nitride, silicon oxynitride, silicon nitride oxide, or other suitable materials. In some embodiments, the sacrifice layer 232 may be formed by, for example, chemical vapor deposition, atomic layer deposition, physical vapor deposition, low-pressure chemical vapor deposition, flowable chemical vapor deposition, or other suitable process.

Referring to FIG. 4C, the supporting frame 204 may be formed on or over the surface 202s1 (or an upper surface) of the sacrifice layer 232. In some embodiments, the material of the supporting frame 204 may be different form that of the sacrifice layer 232. In some embodiments, the supporting frame 204 may be formed by, for example, chemical vapor deposition, atomic layer deposition, physical vapor deposition, low-pressure chemical vapor deposition, flowable chemical vapor deposition, or other suitable process.

Referring to FIG. 4D, a sacrifice layer 234 (or an upper sacrifice layer) may be formed on or over the supporting frame 204. The sacrifice layer 234 may be removed in subsequent processes. In some embodiments, the material of the sacrifice layer 234 may be different from that of the supporting frame 204. The material of the sacrifice layer 234 may be the same as that of the sacrifice layer 232. In some embodiments, the sacrifice layer 234 may include silicon oxide, silicon nitride, silicon oxynitride, silicon nitride oxide, or other suitable materials. In some embodiments, the sacrifice layer 234 may be formed by, for example, chemical vapor deposition, atomic layer deposition, physical vapor deposition, low-pressure chemical vapor deposition, flowable chemical vapor deposition, or other suitable process.

Referring to FIG. 4E, the supporting frame 206 may be formed on or over the sacrifice layer 234. In some embodiments, the material of the supporting frame 206 may be different form that of the sacrifice layer 234. In some embodiments, the supporting frame 206 may be formed by, for example, chemical vapor deposition, atomic layer deposition, physical vapor deposition, low-pressure chemical vapor deposition, flowable chemical vapor deposition, or other suitable process. FIGS. 4B, 4C, 4D, and 4E illustrate a stage corresponding the operation 404 as shown in FIG. 3.

Referring to FIG. 4F, a dielectric layer 242 may be formed on over the supporting frame 206. A dielectric layer 244 may be formed on or over the dielectric layer 242. A photosensitive layer 246 may be formed on or over the dielectric layer 244. The dielectric layer 242 and dielectric layer 244 may collectively function as a hard mask structure to define the pattern of openings for accommodating capacitor components. The dielectric layer 242 may include, for example, polysilicon or other suitable materials. The dielectric layer 244 may include, for example, silicon oxide, silicon oxynitride, or other suitable materials. The photosensitive layer 246 may include a photoresist or other suitable materials. The photosensitive layer 246 may be patterned to expose a portion of the dielectric layer 244. Each of the dielectric layer 242 and dielectric layer 244 may be formed by, for example, chemical vapor deposition, atomic layer deposition, physical vapor deposition, low-pressure chemical vapor deposition, flowable chemical vapor deposition, or other suitable process. The photosensitive layer 246 may be formed by, for example, coating (e.g., spin-on coating), printing, or other suitable processes. The photosensitive layer 246 may be patterned by, for example, soft baking, mask aligning, exposure, post-exposure baking, developing the photoresist, rinsing and drying (e.g., hard baking).

Referring to FIG. 4G, an etching technique P1 (or treatment) may be performed. The dielectric layer 242 and the dielectric layer 244 may be patterned. A portion of the dielectric layer 242 and a portion of the dielectric layer 244 may be removed. A portion of the supporting frame 206 may be exposed. In some embodiments, a portion of the supporting frame 206 may be removed to define a recess. In some embodiments, the etching technique P1 may include one or more stages, and each of the stages may be configured to etch through at least one material.

Referring to FIG. 4H, an etching technique P2 (or treatment) may be performed. The dielectric layer 244 may be removed. The supporting frame 206 may be patterned. The sacrifice layer 234 may be patterned. The supporting frame 204 may be patterned. The sacrifice layer 232 may be patterned. The supporting frame 202 may be patterned. A portion of the supporting frame 202, supporting frame 204, supporting frame 206, sacrifice layer 232, and sacrifice layer 234 may be removed to define openings O1. The pad 146 may be exposed by the openings O1. In some embodiments, a portion of the surface 202s1 may be exposed to the opening O1 due to different etching selectivities to the etchant(s) used in the etching technique P2. The surface 202s2 (or lateral surface) of the supporting frame 202 may be exposed. FIGS. 4F, 4G, and 4H illustrate a stage corresponding the operation 406 as shown in FIG. 3.

Referring to FIG. 4I, an etching technique P3 (or treatment) may be performed. The dielectric layer 242 may be removed. The supporting frame 206 may be exposed.

Referring to FIG. 4J, a derivative of carbide 250 may be formed on or over the surface 202s2 of the supporting frame 202. In some embodiments, the derivative of carbide 250 may be formed by the reaction of the supporting frame 202 to the etchant(s) or gas used in the etching technique P3. In some embodiments, a portion of the supporting frame 202 may be reactive to the etchant(s) or gas (e.g., oxygen) used in the etching technique P3. A portion of the supporting frame 202 may be oxidized. In some embodiments, the derivative of carbide 250 may include oxide. In some embodiments, the derivative of carbide 250 may include oxycarbide and/or boron oxycarbide. The derivative of carbide 250 may include metal oxycarbide (e.g., aluminum oxycarbide, tungsten oxycarbide, titanium oxycarbide, calcium oxycarbide, or other suitable materials). FIGS. 4I and 4J illustrate a stage corresponding the operation 408 as shown in FIG. 3.

Referring to FIG. 4K, an etching technique P4 (or treatment) may be performed. The derivative of carbide 250 may be removed. In some embodiments, the surface 202s2 of the supporting frame 202 may be recessed from a surface 232s1 (or a lateral surface) of the sacrifice layer 232. In some embodiments, the etchant(s) used on the etching technique P4 may include diluted hydrofluoric acid or other suitable etchants. As a result, the width (or aperture) defined by the sacrifice layer 232 may be less than the width (or aperture) defined by the supporting frame 202. FIG. 4K illustrates a stage corresponding the operation 410 as shown in FIG. 3.

Referring to FIG. 4L, the lower electrode 212 may be formed. The lower electrode 212 may be formed on the upper surface of the supporting frame 206. The lower electrode 212 may be formed on the sidewall (or lateral surface) of the sacrifice layer 234. The lower electrode 212 may be formed on the sidewall (or lateral surface) of the supporting frame 204. The lower electrode 212 may be formed on the surface 232s1 of the sacrifice layer 232. The lower electrode 212 may be formed on the surface 202s2 of the supporting frame 202. In some embodiments, the lower electrode 212 may extend outwardly and horizontally since the supporting frame 202 is recessed from the surface 232s1 of the sacrifice layer 232. The lower electrode 212 may be formed on and in contact with the pad 146. In some embodiments, the lower electrode 212 may be formed by, for example, physical vapor deposition, atomic layer deposition, chemical vapor deposition, low-pressure chemical vapor deposition, flowable chemical vapor deposition, or other suitable process. FIG. 4L illustrates a stage corresponding the operation 412 as shown in FIG. 3.

Referring to FIG. 4M, a portion of the lower electrode 212 may be removed. A portion of the supporting frame 206 may be removed. A portion of the sacrifice layer 234 may be removed. The supporting frame 206, lower electrode 212, and sacrifice layer 234 may be removed by, for example, a dry etching technique.

Referring to FIG. 4N, the sacrifice layer 234 may be removed. The sacrifice layer 232 may be removed. The supporting frame 204 may be exposed. The lower surface of the supporting frame 206 may be exposed. The surface 202s1 of the supporting frame 202 may be exposed. FIGS. 4M and 4N illustrate a stage corresponding the operation 414 as shown in FIG. 3.

Referring to FIG. 4O, the capacitor dielectric 214 may be formed on the lower electrode 212. The capacitor dielectric 214 may be formed on the supporting frame 204. The upper electrode 216 may be formed on the capacitor dielectric 214. Each of the capacitor dielectric 214 and upper electrode 216 may be formed by, atomic layer deposition, chemical vapor deposition, physical vapor deposition, low-pressure chemical vapor deposition, flowable chemical vapor deposition, or other suitable process. FIG. 4O illustrates a stage corresponding the operation 416 as shown in FIG. 3.

Referring to FIG. 4P, the grounding electrode 220 may be formed on the supporting frame 206. The grounding electrode 220 may be formed by, chemical vapor deposition, atomic layer deposition, physical vapor deposition, low-pressure chemical vapor deposition, flowable chemical vapor deposition, or other suitable process. As a result, the device 200 may be produced. FIG. 4P illustrates a stage corresponding the operation 418 as shown in FIG. 3.

One aspect of the present disclosure provides a semiconductor device. The semiconductor device includes a substrate, a lower supporting frame; an upper supporting frame, and a capacitor component. The lower supporting frame is disposed over the substrate. The upper supporting frame is disposed over and spaced apart from the lower supporting frame. The capacitor component is disposed over the substrate. The capacitor component includes a lower electrode having a noncontinuous sidewall abutting the lower supporting frame.

Another aspect of the present disclosure provides a semiconductor device. The semiconductor device includes a substrate, a capacitor component, and a grounding electrode. The substrate includes a pad. The capacitor component is electrically connected to the pad. The grounding electrode is electrically connected to the capacitor component. The grounding electrode has a neck portion over the pad.

Another aspect of the present disclosure provides a method of manufacturing a semiconductor device. The method includes: providing a substrate having a pad; forming a first dielectric layer over the substrate; forming a sacrifice layer over the substrate; forming a second dielectric layer over the sacrifice layer; patterning the first dielectric layer, the sacrifice layer, and the second dielectric layer to form an opening over the pad, wherein the opening has a first width defined by the first dielectric layer and a second width defined by the sacrifice layer, and the first width is greater than the second width; and forming a capacitor component within the opening.

The embodiments of the present disclosure illustrate a semiconductor device including a capacitor component supported by an upper supporting frame and a lower supporting frame. The lower supporting frame defines an opening with a relatively large dimension (e.g., width or diameter) over the landing pad of the transistor, and the upper supporting frame defines the opening with a relatively small dimension (e.g., width or diameter). As a result, the leakage between abutting capacitor components can be prevented, while a relatively lower resistance can be achieved due to a larger contact area between the landing pad and the capacitor component. The material of the lower supporting frame can be different from that of the upper supporting frame to facilitate the formation of said opening.

Although the present disclosure and its advantages have been described in detail, it should be understood that various changes, substitutions and alterations may be made herein without departing from the spirit and scope of the disclosure as defined by the appended claims. For example, many of the processes discussed above may be implemented in different methodologies and replaced by other processes, or a combination thereof.

Moreover, the scope of the present application is not intended to be limited to the particular embodiments of the process, machine, manufacture, and composition of matter, means, methods and steps described in the specification. As one of ordinary skill in the art will readily appreciate from the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, or steps.

What is claimed is:

1. A semiconductor device, comprising:
a carrier comprising a pad;
a capacitor component electrically connected to the pad; and
a grounding electrode electrically connected to the capacitor component, wherein the grounding electrode has a neck portion over the pad.

2. The semiconductor device of claim 1, wherein the neck portion of the grounding electrode is directly over the pad.

3. The semiconductor device of claim 1, further comprising:
a lower supporting frame disposed over the carrier; and
an upper supporting frame disposed over and spaced apart from the lower supporting frame, wherein the capacitor component comprises a lower electrode extends outwardly abutting the lower supporting frame.

4. The semiconductor device of claim 1, wherein the capacitor component comprises a capacitor dielectric extending outwardly abutting the lower supporting frame.

5. The semiconductor device of claim 1, wherein the capacitor component comprises an upper electrode spaced apart from the lower electrode, and the upper electrode extends outwardly abutting the lower supporting frame.

6. The semiconductor device of claim 1, further comprising:
a lower supporting frame disposed over the carrier; and
an upper supporting frame disposed over and spaced apart from the lower supporting frame, wherein the grounding electrode has a first width abutting an upper surface of the lower supporting frame and a second width abutting the carrier, and the first width is greater than the second width.

7. The semiconductor device of claim 6, wherein a material of the lower supporting frame is different from that of the upper supporting frame.

8. The semiconductor device of claim 6, wherein the carrier comprises a passivation layer surrounding the pad, and the passivation layer has a recess.

9. The semiconductor device of claim 8, wherein the lower supporting frame fills the recess.

10. The semiconductor device of claim 6, wherein a material of the lower supporting frame comprises silicon carbide, silicon oxycarbide, or a combination thereof.

11. The semiconductor device of claim 3, wherein the lower electrode defines an opening having a first width abutting an upper surface of the lower supporting frame and a second width abutting the carrier, and the first width is greater than the second width.

12. The semiconductor device of claim 6, further comprising:
a middle supporting frame disposed between the lower supporting frame and the upper supporting frame.
